(19) United States
(12) Patent Application Publication
(10) Pub. No.: US 2024/0284658 A1
(43) Pub. Date: Aug. 22, 2024

(54) SEMICONDUCTOR DEVICE AND METHOD FOR MANUFACTURING THE SAME

(71) Applicant: SAMSUNG ELECTRONICS CO., LTD., Suwon-si (KR)

(72) Inventors: Minkyung KANG, Suwon-si (KR); Seohee PARK, Suwon-si (KR); Yong-Suk TAK, Suwon-si (KR); Joonnyung HEO, Suwon-si (KR)

(21) Appl. No.: 18/381,248

(22) Filed: Oct. 18, 2023

(30) Foreign Application Priority Data
Feb. 21, 2023 (KR) 10-2023-0023106

(51) Int. Cl. H10B 12/00

(52) U.S. Cl. CPC H10B 12/482; H10B 12/02; H10B 12/315; H10B 12/485

(57) ABSTRACT

The present disclosure relates to a semiconductor device and a method for manufacturing the same, and the semiconductor device according to an embodiment includes: a substrate including an active region defined by an element isolation layer; a word line crossing the active region; a bit line crossing the active region in a direction different from the word line; a direct contact connecting between the active region and the bit line; a buried contact connected to the active region; and a bit line spacer that is disposed between the bit line and the buried contact and includes carbon. The bit line spacer includes a first region that is adjacent to the bit line and has a first carbon content and a second region that is adjacent to the buried contact and has a second carbon content that is higher than the first carbon content.

### CROSS-REFERENCE TO RELATED APPLICATION

This application claims priority to and the benefit of Korean Patent Application No. 10-2023-0023106 filed in the Korean Intellectual Property Office on Feb. 21, 2023, the entire contents of which are incorporated herein by reference.

### BACKGROUND

### 1. Field

The disclosure relates to a semiconductor device and a method for manufacturing (fabricating) the same.

### 2. Description of the Related Art

As a semiconductor device becomes increasingly highly integrated, an individual circuit pattern is becoming finer in order to provide more semiconductor devices in the same area. That is, as a degree of integration of the semiconductor device increases, design rules for components of the semiconductor devices are increasing.

In a highly scaled semiconductor device, a process of forming a plurality of wire lines, a plurality of buried contacts (BC) interposed between the plurality of wire lines, a spacer protecting a plurality of wires, or the like is becoming increasingly complicated and difficult.

### SUMMARY

Embodiments are directed to a semiconductor device with improved reliability and productivity and a method for manufacturing the semiconductor device according to an embodiment.

A semiconductor device according to an embodiment includes: a substrate including an active region defined by an element isolation layer; a word line crossing the active region; a bit line crossing the active region in a direction different from the word line; a direct contact connecting between the active region and the bit line; a buried contact connected to the active region; and a bit line spacer that is disposed between the bit line and the buried contact and includes carbon. The bit line spacer includes a first region that is adjacent to the bit line and has a first carbon content and a second region that is adjacent to the buried contact and has a second carbon content that is higher than the first carbon content.

A semiconductor device according to another embodiment may include a substrate including an active region defined by an element isolation layer; a word line crossing the active region; a bit line crossing the active region in a direction different from the word line; a direct contact connecting between the active region and the bit line; a buried contact connected to the active region; and a bit line spacer that extends along a sidewall of the bit line and includes at least one of SiOCN, SiOC, and SiOCF. The bit line spacer includes a first region, a second region, and a third region sequentially disposed from a first surface adjacent to the bit line to a second surface adjacent to the buried contact, the first region has a first carbon content, the second region has a second carbon content that is greater than the first carbon content, and the third region has a third carbon content that is greater than the second carbon content.

Embodiments may further provide a method for manufacturing the semiconductor device according to an embodiment including forming an element isolation layer within a substrate to define an active region, forming a word line and a bit line crossing the active region in different directions, forming a bit line spacer including a first region, a second region, and a third region having different carbon contents to cover the bit line, patterning the bit line spacer to remove at least a portion of the second region and the third region of the bit line spacer; and forming a buried contact outside the bit line spacer. The forming of the bit line spacer includes: forming the first region having a first carbon content outside the bit line, forming the second region having a second carbon content that is higher than the first carbon content outside the first region, and forming the third region having a third carbon content that is higher than the second carbon content outside the second region.

Embodiments also provide a semiconductor device with improved reliability and productivity and a method for manufacturing the semiconductor device.

According to the embodiments, a semiconductor device having an improved electrical characteristic may be provided since a bit line spacer having excellent etching resistance and an electrical characteristic is disposed above or on a side surface of a bit line.

### BRIEF DESCRIPTION OF THE DRAWINGS

Features will become apparent to those of skill in the art by describing in detail exemplary embodiments with reference to the attached drawings in which:

FIG. 1 is a plan view illustrating a semiconductor device according to an embodiment.

FIG. 2 is a cross-sectional view taken along a line I-I′ in FIG. 1.

FIG. 3 is a cross-sectional view taken along a line II-II′ of FIG. 1.

FIG. 4 is an enlarged cross-sectional view showing an enlarged region A of FIG. 2.

FIGS. 5 and 6 are graphs schematically illustrating a carbon content according to a position within a third spacer according to an embodiment.

FIG. 7 is an enlarged cross-sectional view illustrating the enlarged region A of FIG. 2 according to another embodiment.

FIGS. 8 to 10 are graphs schematically illustrating the carbon content according to a position within the third spacer according to an embodiment.

FIGS. 11 and 12 are enlarged cross-sectional views illustrating the enlarged region A of FIG. 2 according to another embodiment.

FIGS. 13 to 16 are graphs schematically illustrating the carbon content according to a position within the third spacer according to an embodiment.

FIGS. 17 to 25 are cross-sectional views illustrating a method for manufacturing the semiconductor device according to an embodiment.

FIG. 26 is a conceptual view schematically illustrating equipment for forming the third spacer according to an embodiment.

FIG. 27 is a timing diagram illustrating a supply cycle of sources according to an embodiment.

FIG. 28 is a timing diagram illustrating any one of supply cycles of the sources according to an embodiment.

FIG. 29 is a timing diagram illustrating a supply cycle of the sources according to another embodiment.

FIG. 30 is an enlarged view of a region B of FIG. 25.

FIGS. 31 and 33 are cross-sectional views illustrating a method for manufacturing the semiconductor device according to an embodiment.

FIG. 32 is an enlarged view of a region C of FIG. 31.

### DETAILED DESCRIPTION

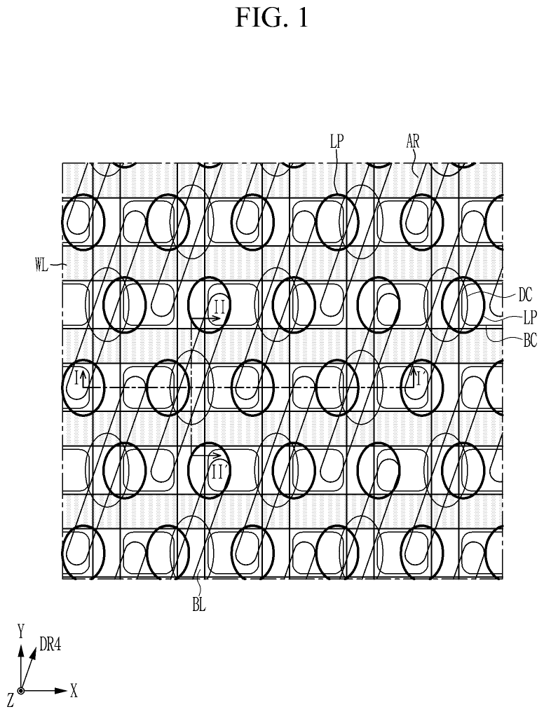

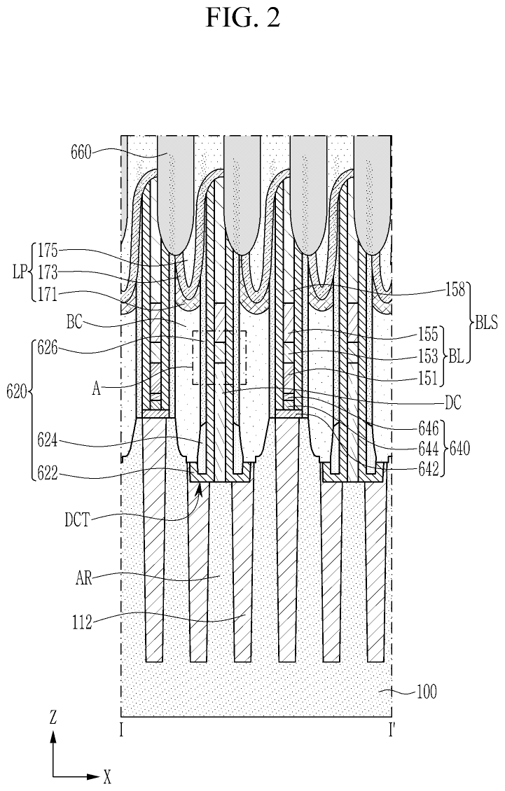

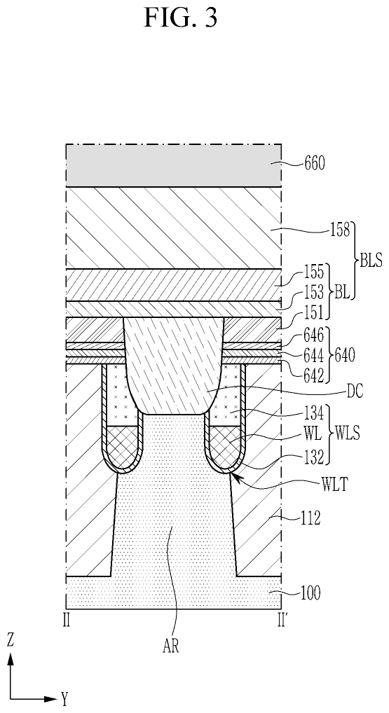

FIG. 1 is a plan view illustrating a semiconductor device according to an embodiment. FIG. 2 is a cross-sectional view taken along a line I-I′ of FIG. 1. FIG. 3 is a cross-sectional view taken along a line II-II′ of FIG. 1.

As shown in FIGS. 1 to 3, the semiconductor device according to the embodiment may include an active region AR, a word line WL and a bit line BL that crosses to overlap the active region AR.

The active region AR may be defined by an element isolation layer (or a device separation layer) 112 disposed within a substrate 100. A plurality of active regions AR may be disposed within the substrate 100, and the plurality of active regions AR are separated from each other by the element isolation layer 112. The element isolation layer 112 may be disposed on both sides of each active region AR.

The substrate 100 may include a semiconductor material. For example, the substrate 100 may include a group IV semiconductor, a group III-V compound semiconductor, a group II-VI compound semiconductor, or the like. The substrate 100 may include a semiconductor such as, for example, Si or Ge or a compound semiconductor such as SiGe, SiC, GaAs, InAs, or InP, as non-limiting examples that may be variously changed.

The substrate 100 may have an upper surface parallel to a first direction (an X direction) and a second direction (a Y direction), and may have a thickness that is parallel to a third direction (a Z direction) perpendicular to the first direction (X direction) and the second direction (Y direction).

The active region AR may have a rod shape extending along a fourth direction DR4 oblique with respect to the first direction (X direction) and the second direction (Y direction). The fourth direction DR4 may be parallel to the upper surface of the substrate 100, and may be disposed on the same plane as the first direction (X direction) and the second direction (Y direction). The fourth direction DR4 may form an acute angle with the first direction (X direction) and the second direction (Y direction).

The plurality of active regions AR may extend in parallel directions. The plurality of active regions AR may be spaced apart from each other by a predetermined interval along the fourth direction DR4 and the first direction (X direction). A central portion of one active region AR may be adjacent to an end portion of another active region AR in the first direction (X direction). An end portion of one side of the one active region AR may be adjacent to the other end portion of the other active region AR in a first direction (X direction). However, a shape or a disposition of the active region AR is not limited thereto, and may be variously changed.

The substrate 100 may include a cell array region and a peripheral circuit region. The cell array region may be a region where a plurality of memory cells are formed. The plurality of active regions AR may be disposed at the cell array region. The peripheral circuit region may be disposed to surround the cell array region, and elements driving the memory cells may be disposed therein. FIGS. 1 to 3 illustrate the cell array region for convenience of description, and illustration of the peripheral circuit region is omitted.

The element isolation layer 112 may have a shallow trench isolation (STI) structure having an excellent element isolation characteristic. The element isolation layer 112 may be made of a silicon oxide, a silicon nitride, or a combination thereof. However, a material of the element isolation layer 112 is not limited thereto, and may be variously changed.

The element isolation layer 112 may be formed of a single layer or multiple layers. The element isolation layer 112 may be made of a single material or may include two or more types of insulating materials.

The word line WL may extend along the first direction (X direction), and may cross the active region AR. The word line WL may overlap the active region AR, and may serve as a gate electrode. One of the word lines WL may overlap the plurality of active regions AR adjacent along the first direction (X direction). A plurality of word lines WL may extend in parallel in the first direction (X direction), and may be spaced apart from each other at regular intervals along the second direction (Y direction).

Each of the plurality of active regions AR may overlap to cross two word lines WL. Each active region AR may be divided into three portions by the two word lines WL. In this case, the central portion of the active region AR disposed between the two word lines WL may be a portion connected to the bit line BL, and both end portions of the active region AR disposed outside the two word lines WL may be a portion connected to a capacitor (not shown). The bit line BL may be connected to the active region AR through a direct contact DC. The capacitor may be connected to the active region AR through a landing pad LP and a buried contact BC.

A word line trench WLT may be formed in the substrate 100, and a word line structure WLS may be disposed within the word line trench WLT. That is, the word line structure WLS may have a form buried within the substrate 100. A portion of the word line trench WLT may be disposed on the active region AR, and another portion of the word line trench WLT may be disposed on the element isolation layer 112.

The word line structure WLS may include a gate insulating layer 132, a word line WL disposed on the gate insulating layer 132, and a word line capping layer 134 disposed on the word line WL. However, a position, a shape, a structure, or the like of the word line structure WLS is not limited thereto, and may be variously changed.

The gate insulating layer 132 may be disposed within the word line trench WLT. The gate insulating layer 132 may be conformally formed on an inner wall surface of the word line trench WLT. The gate insulating layer 132 may include a silicon oxide, a silicon nitride, a silicon oxynitride, a high-k material (a high dielectric constant material) having a higher dielectric constant than the silicon oxide, or a combination thereof. However, a position, a shape, a material, or the like of the gate insulating layer 132 is not limited thereto, and may be variously changed.

The word line WL may be disposed at both sides of the direct contact DC. Side and bottom surfaces of the word line WL may be surrounded by the gate insulating layer 132. The gate insulating layer 132 may be disposed between the word line WL and the active region AR. Therefore, the word line WL may not directly contact the active region AR.

The word line WL may include, for example, Ti, TiN, Ta, TaN, W, WN, TiSiN, WSiN, a polysilicon, or a combination thereof. However, a position, a shape, a material, or the like of the word line WL is not limited thereto, and may be variously changed.

The word line capping layer 134 may be disposed on the word line WL. The word line capping layer 134 may entirely cover an upper surface of the word line WL. A lower surface of the word line capping layer 134 may contact the word line WL. A side surface of the word line capping layer 134 may be covered by the gate insulating layer 132. The word line capping layer 134 may include a silicon oxide, a silicon nitride, a silicon oxynitride, or a combination thereof. However, a position, a shape, a material, or the like of the word line capping layer 134 is not limited thereto, and may be variously changed.

The word line WL may be disposed at both sides of the direct contact DC. The word line WL and the direct contact DC may overlap each other in the third direction (Z direction). An upper surface of the word line WL may be disposed at a lower level than a lower surface of the direct contact DC. The word line capping layer 134 may be disposed between the word line WL and the direct contact DC. Thus, the word line WL and the direct contact DC may be insulated by the word line capping layer 134. However, a positional relationship between the word line WL and the direct contact DC is not limited thereto, and may be variously changed.

The bit line BL may extend along the second direction (Y direction), and may cross the active region AR and the word line WL. In this case, the bit line BL may vertically cross the word line WL. The bit line BL may be disposed above the word line WL.

One bit line BL may overlap the plurality of active regions AR adjacent along the second direction (Y direction). The bit line BL may be connected to the active region AR through the direct contact DC. The one bit line BL may be connected to the plurality of active regions AR adjacent along the second direction (Y direction). Each of the plurality of active regions AR may be connected to the one bit line BL. A central portion of the active region AR may be connected to the bit line BL. However, this is only an example, and a connection form of the bit line BL and the active region AR may be variously changed.

A plurality of bit lines BL may extend in parallel in the second direction (Y direction), and may be spaced apart from each other at regular intervals along the first direction (X direction).

A direct contact trench DCT may be formed in the substrate 100, and the direct contact DC may be disposed within the direct contact trench DCT. The direct contact trench DCT may be disposed on the active region AR, and the direct contact DC may be connected to the active region AR. The direct contact DC may be directly connected to the active region AR. The direct contact DC may overlap the active region AR in the third direction (Z direction). The direct contact DC may include a conductive material. The direct contact DC may include, for example, a polysilicon doped with an impurity or a metal such as W, Mo, Au, Cu, Al, Ni, Co, or the like.

The bit line BL may be disposed above or on the substrate 100 and the direct contact DC. The bit line BL may include a first conductive layer 151, a second conductive layer 153, and a third conductive layer 155 sequentially stacked.

The first conductive layer 151, the second conductive layer 153, and the third conductive layer 155 may include a conductive material. For example, the first conductive layer 151 may include a polysilicon doped with an impurity. or a metal such as W, Mo, Au, Cu, Al, Ni, Co, or the like. The second conductive layer 153 may include a metal such as Ti, Ta, or the like and/or a metal nitride such as TiN, TaN, or the like. The third conductive layer 155 may include a metal such as W, Mo, Au, Cu, Al, Ni, Co, or the like. However, structures and materials of conductive layers constituting the bit line BL are not limited thereto, and may be variously changed.

The bit line BL may directly contact the direct contact DC. The first conductive layer 151 of the bit line BL may contact a side surface of the direct contact DC, and the second conductive layer 153 of the bit line BL may contact an upper surface of the direct contact DC. The direct contact DC may be disposed between the active region AR and the bit line BL, and may electrically connect the active region AR and the bit line BL. That is, the bit line BL may be connected to the active region AR through the direct contact DC.

The first conductive layer 151 among the conductive layers constituting the bit line BL and the direct contact DC may include the same material. For example, the first conductive layer 151 and the direct contact DC may include a polysilicon doped with an impurity. In some implementations, the first conductive layer 151 and the direct contact DC may include different materials.

A bit line capping layer 158 may be disposed on the bit line BL. The bit line BL and the bit line capping layer 158 may form a bit line structure BLS. The bit line capping layer 158 may overlap the bit line BL and the direct contact DC in the third direction (Z direction). The bit line BL and the direct contact DC may be patterned using the bit line capping layer 158 as a mask. A planar shape of the bit line BL may be substantially the same as that of the bit line capping layer 158. The bit line capping layer 158 is illustrated as being in contact with the third conductive layer 155 of the bit line BL, but the disclosure is not limited thereto. Another layer may be further disposed between the bit line capping layer 158 and the third conductive layer 155 of the bit line BL.

The bit line capping layer 158 may include a silicon nitride. However, a material of the bit line capping layer 158 is not limited thereto, and may be variously changed.

A spacer structure 620 may be disposed at both sides of the bit line structure BLS. The spacer structure 620 may cover side surfaces of the bit line capping layer 158, the bit line BL, and the direct contact DC. The spacer structure 620 may extend approximately in the third direction (Z direction) along a side surface of the bit line structure BLS. At least a portion of the spacer structure 620 may be disposed within the direct contact trench DCT. Within the direct contact trench DCT, the spacer structure 620 may be disposed at both sides of the direct contact DC.

The spacer structure 620 may be formed of multiple layers made of a combination of various types of insulating materials.

The spacer structure 620 may include a first spacer 622, a second spacer 624, and a third spacer 626. However, the disclosure is not limited thereto, and the number and a structure of layers constituting the spacer structure 620 may be variously changed.

Further, the spacer structure 620 may be formed of a single layer. In an embodiment, the spacer structure 620 may be formed of an air spacer structure that is surrounded by spacers to have an air space.

The first spacer 622 may cover side surfaces of the bit line structure BLS and the direct contact DC. Within the direct contact trench DCT, the first spacer 622 may be formed to cover bottom and side surfaces of the direct contact trench DCT.

The second spacer 624 may be disposed on the first spacer 622. A lower surface and a side surface of the second spacer 624 may be surrounded by the first spacer 622. The second spacer 624 may be disposed within the direct contact trench DCT. The second spacer 624 may be formed to fill the direct contact trench DCT. The second spacer 624 may be disposed at both sides of the direct contact DC within the direct contact trench DCT.

The third spacer 626 may be disposed on the first spacer 622 and the second spacer 624. The third spacer 626 may overlap the first spacer 622 along the first direction (X direction), and may overlap the second spacer 624 along the third direction (Z direction). The third spacer 626 may extend approximately in the third direction (Z direction) along a side surface of the first spacer 622. The third spacer 626 may extend parallel to the first spacer 622.

The spacer structure 620 may include an insulating material. The first spacer 622 and the second spacer 624 may include the same material, and the third spacer 626 may include a material different from that of each of the first spacer 622 and the second spacer 624. In some implementations, the first spacer 622, the second spacer 624, and the third spacer 626 may include different materials.

Each of the first spacer 622 and the second spacer 624 may include at least one of a silicon nitride, a silicon oxynitride, a silicon oxide, a silicon oxycarbide (SiOC), a silicon carbon nitride (SiCN), a silicon oxycarbonitride (SiOCN), and a combination thereof. The third spacer 626 may include at least one of SiOCN, SiOC, SiOCF, and a combination thereof. However, a material of the spacer structure 620 is not limited thereto, and may be variously changed.

An insulating layer 640 may be disposed below the bit line BL. The insulating layer 640 may be disposed between the bit line BL and the element isolation layer 112. The direct contact DC may be disposed between the bit line BL and the active region AR. The insulating layer 640 may not be disposed between the bit line BL and the active region AR.

The insulating layer 640 may be disposed on the word line structure WLS. The insulating layer 640 may be disposed between the word line structure WLS and the bit line BL. The insulating layer 640 may include a first insulating layer 642, a second insulating layer 644, and a third insulating layer 646 sequentially stacked.

At least some of the first insulating layer 642, the second insulating layer 644, and the third insulating layer 646 may have different widths. Widths of the second insulating layer 644 and the third insulating layer 646 may be substantially the same. The widths of the second insulating layer 644 and the third insulating layer 646 may be substantially the same as those of the bit line BL and the bit line capping layer 158. A width of the first insulating layer 642 may be different from that of each of the second insulating layer 644 and the third insulating layer 646. The width of the first insulating layer 642 may be greater than that of each of the second insulating layer 644 and the third insulating layer 646. Accordingly, the width of the first insulating layer 642 may be greater than that of the bit line BL.

The insulating layer 640 may be covered by the spacer structure 620. For example, an upper surface of the first insulating layer 642 may be covered by the first spacer 622. Side surfaces of the second insulating layer 644 and the third insulating layer 646 may be covered by the first spacer 622.

The insulating layer 640 may include an insulating material. Each of the first insulating layer 642, the second insulating layer 644, and the third insulating layer 646 may include an insulating material. For example, the first insulating layer 642 may include a silicon oxide. The second insulating layer 644 may include a material having an etching selectivity different from that of the first insulating layer 642. For example, the second insulating layer 644 may include a silicon nitride and the third insulating layer 646 may include a silicon oxide or a silicon nitride. However, a structure, a material, or the like of the insulating layer 640 is not limited thereto, and may be variously changed.

The buried contact BC may be disposed between the plurality of bit lines BL. The semiconductor device according to the embodiment may include a plurality of buried contacts BC. The plurality of buried contacts BC may be disposed to be spaced apart from each other in the first direction (X direction) and the second direction (Y direction). For example, the plurality of buried contacts BC may be disposed to be spaced apart from each other in the second direction (Y direction) between two adjacent bit lines BL. In addition, the plurality of buried contacts BC may be disposed to be spaced apart from each other in the first direction (X direction) between two adjacent word lines WL. However, a disposition form of the plurality of buried contacts BC is not limited thereto, and may be variously changed.

At least a portion of the buried contact BC may overlap the active region AR in the third direction (Z direction), and another portion of the buried contact BC may overlap the element isolation layer 112 in the third direction (Z direction). The buried contact BC may be electrically connected to the active region AR. The buried contact BC may directly contact the active region AR. At least a portion of lower and side surfaces of the buried contact BC is surrounded by the active region AR. However, the disclosure is not limited thereto, and another layer may be further disposed between the buried contact BC and the active region AR, and the buried contact BC may be connected to the active region AR through the other layer.

The buried contact BC may include a conductive material. For example, the buried contact BC may include a polysilicon doped with an impurity, but the disclosure is not limited thereto.

The spacer structure 620 may be disposed above or on both side surfaces of the buried contact BC. The spacer structure 620 may be disposed between the buried contact BC and the bit line BL. For example, one side surface of the buried contact BC may contact the third spacer 626 and the active region AR, and the other side surface of the buried contact BC may contact the third spacer 626 and the second spacer 624.

A lower surface of the buried contact BC may contact the first spacer 622. However, this is only an example, and a positional relationship between the buried contact BC and the spacer structure 620 may be variously changed.

An upper surface of the buried contact BC may be disposed at a level lower than of an upper surface of the bit line BL. A lower surface of the buried contact BC may be disposed at a level higher than that of a lower surface of the direct contact DC. However, the disclosure is not limited thereto, and a positional relationship between the buried contact BC, the bit line BL, and the direct contact DC may be variously changed.

The landing pad LP may be disposed on the buried contact BC. A plurality of landing pads LP may be disposed to be spaced apart from each other in the first direction (X direction) and the second direction (Y direction). The plurality of landing pads LP may be disposed in a line along the first direction (X direction). The plurality of landing pads LP may be disposed in a zigzag shape along the second direction (Y direction). For example, the plurality of landing pads LP may be alternately disposed at left and right sides of the bit line BL. However, a disposition form of the plurality of landing pads LP is not limited thereto, and may be variously changed.

The landing pad LP may cover an upper surface of the buried contact BC and may overlap the buried contact BC in the third direction (Z direction). At least a portion of the landing pad LP may overlap the spacer structure 620 in the third direction (Z direction) and may overlap the bit line BL in the third direction (Z direction). An upper surface of the landing pad LP may be disposed at a level higher than that of an upper surface of the bit line capping layer 158. The spacer structure 620 may be disposed above or on both side surfaces of the landing pad LP. The spacer structure 620 may be disposed between the landing pad LP and the bit line BL and between the landing pad LP and the bit line capping layer 158. The landing pad LP may be electrically connected to the buried contact BC. The landing pad LP may directly contact the buried contact BC. The landing pad LP may be electrically connected to the active region AR through the buried contact BC.

The landing pad LP may include a metal silicide layer 171, a conductive barrier layer 173, and a conductive layer 175.

The metal silicide layer 171 may be disposed on the buried contact BC, the conductive barrier layer 173 may be disposed on the metal silicide layer 171, and the conductive layer 175 may be disposed on the conductive barrier layer 173.

The metal silicide layer 171 may directly contact the buried contact BC. The metal silicide layer 171 may entirely cover an upper surface of the buried contact BC. An upper surface of the buried contact BC may have a concave shape, and the metal silicide layer 171 may have a concave shape along the upper surface of the buried contact BC. The spacer structure 620 may be disposed above or on both side surfaces of the metal silicide layer 171. The metal silicide layer 171 may include a metal silicide material such as a cobalt silicide, a nickel silicide, a manganese silicide, or the like. However, a shape, a material, or the like of the metal silicide layer 171 is not limited thereto, and may be variously changed. In an embodiment, the metal silicide layer 171 may be omitted.

The conductive barrier layer 173 may be disposed between the metal silicide layer 171 and the conductive layer 175. A lower surface of the conductive barrier layer 173 may contact the metal silicide layer 171. The spacer structure 620 may be disposed above or on both side surfaces of the conductive barrier layer 173. For example, the conductive barrier layer 173 may cover upper surfaces of the first spacer 622 and the third spacer 626.

The conductive barrier layer 173 may contact the first spacer 622 and the third spacer 626. The conductive barrier layer 173 may include Ti, TiN, or a combination thereof. However, a shape, a material, or the like of the conductive barrier layer 173 is not limited thereto, and may be variously changed.

A lower surface of the conductive layer 175 may contact the conductive barrier layer 173. At least a portion of a lower surface and a side surface of the conductive layer 175 may be surrounded by the conductive barrier layer 173. The conductive barrier layer 173 may be disposed between the conductive layer 175 and the metal silicide layer 171. The conductive barrier layer 173 may be disposed between the conductive layer 175 and the spacer structure 620.

The conductive layer 175 may include a metal, a metal nitride, a polysilicon doped with an impurity, or a combination thereof. For example, the conductive layer 175 may include W. However, a shape, a material, or the like of the conductive layer 175 is not limited thereto, and may be variously changed.

An insulating pattern 660 may be disposed between the plurality of landing pads LP. The insulating pattern 660 may be formed to fill a space between the plurality of landing pads LP. The plurality of landing pads LP may be separated from each other by the insulating pattern 660.

The landing pad LP may include a silicon nitride, a silicon oxynitride, a silicon oxide, or a combination thereof. The landing pad LP may be formed of a single layer or multiple layers. For example, the landing pad LP may include a first material layer and a second material layer that are stacked. In this case, the first material layer may include a silicon oxide or a low-k material (a low dielectric constant material) having a low dielectric constant such as SiOCH and SiOC, and the second material layer may include a silicon nitride or a silicon oxynitride. However, a shape, a material, or the like of the landing pad LP is not limited thereto, and may be variously changed.

Although illustration is omitted, a capacitor structure may be disposed above or on the landing pad LP. The capacitor structure may include a first capacitor electrode, a second capacitor electrode, and a dielectric layer disposed between the first capacitor electrode and the second capacitor electrode.

The first capacitor electrode may contact the landing pad LP, and may be electrically connected to the landing pad LP. The capacitor structure may be electrically connected to the active region AR through the landing pad LP and the buried contact BC.

The first capacitor electrode may be disposed above or on each landing pad LP, and a plurality of first capacitor electrodes may be disposed to be separated from each other. The same voltage may be applied to second capacitor electrodes of a plurality of capacitor structures, and the second capacitor electrodes of a plurality of capacitor structures may be integrally formed. Dielectric layers of the plurality of capacitor structures may be integrally formed.

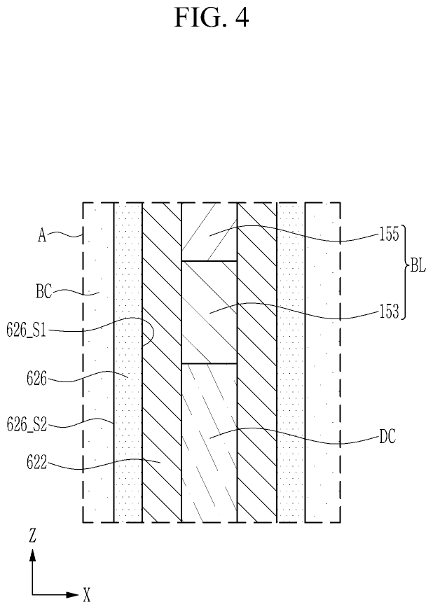

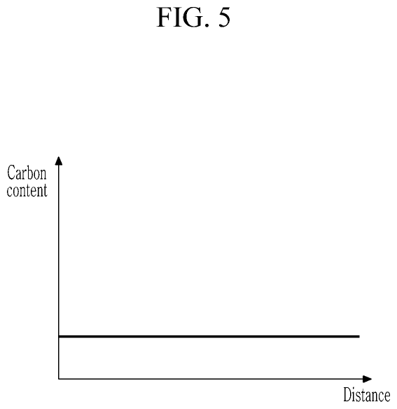

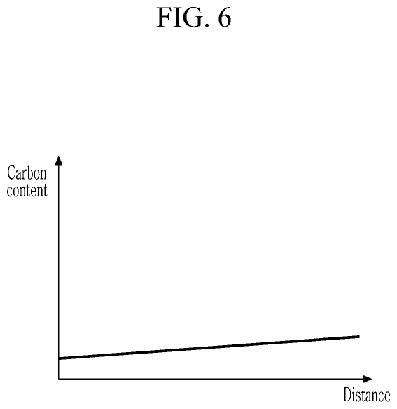

FIG. 4 is an enlarged cross-sectional view showing an enlarged region A of FIG. 2. FIGS. 5 and 6 are graphs schematically illustrating a carbon content according to a position within the third spacer according to an embodiment.

Referring to FIG. 4, the third spacer 626 may be disposed between the first spacer 622 and the buried contact BC. The third spacer 626 may include a first surface 626_S1 contacting the first spacer 622 and a second surface 626_S2 contacting the buried contact BC.

In FIG. 5, an X-axis indicates the position within the third spacer 626, and a Y-axis indicates the carbon content according to the position within the third spacer 626. Specifically, referring to FIGS. 5 and 6 together with FIG. 4 the closer to an origin on the graph, the closer to the first surface 626_S1 of the third spacer 626, and the further from the origin, the closer to the second surface 626_S2 of the third spacer 626. That is, the closer to the origin on the graph, the closer to the bit line BL from a central portion of the third spacer 626, and the further from the origin, the closer to the buried contact BC from the central portion of the third spacer 626.

In an embodiment, the third spacer 626 may have a constant carbon content regardless of the position. That is, a carbon content of a region adjacent to the first surface 626_S1 within the third spacer 626, a carbon content of a region disposed at the central portion of the third spacer 626, and a carbon content of a region adjacent to the second surface 626_S2 within the third spacer 626 may be substantially the same. However, the carbon content according to the position within the third spacer 626 is not limited to the embodiment shown in FIG. 5.

In an embodiment, as shown in FIG. 6, the third spacer 626 may have a different carbon content depending on a position within the third spacer 626. Specifically, referring to FIG. 6 together with FIG. 4, the carbon content within the third spacer 626 may increase from the first surface 626_S1 of the third spacer 626 to the second surface 626_S2 of the third spacer 626. That is, a carbon content of a region adjacent to the first surface 626_S1 within the third spacer 626 may be less than a carbon content of a region adjacent to the second surface 626_S2 within the third spacer 626.

FIG. 6 shows that the carbon content within the third spacer 626 constantly increases from the first surface 626_S1 of the third spacer 626 to the second surface 626_S2 of the third spacer 626, but the disclosure is not limited thereto. For example, the carbon content within the third spacer 626 may increase from the first surface 626_S1 to the second surface 626_S2, or the carbon content may decrease or may increase. In some implementations, a change in the carbon content may occur stepwise.

In an embodiment, the carbon content within the third spacer 626 may be about 5 at % or less. When the third spacer 626 has a carbon content of about 5 at % or less, a dielectric constant of the third spacer 626 may be reduced. That is, the dielectric constant of the third spacer 626 may change according to a composition of a material included in the third spacer 626. When the third spacer 626 has a carbon content of about 5 at % or less, the dielectric constant of the third spacer 626 may be reduced.

As the third spacer 626 has a low dielectric constant even if the third spacer 626 has a thin thickness, parasitic capacitance between the bit line BL and the buried contact BC may be reduced, and generation of leakage current may be prevented.

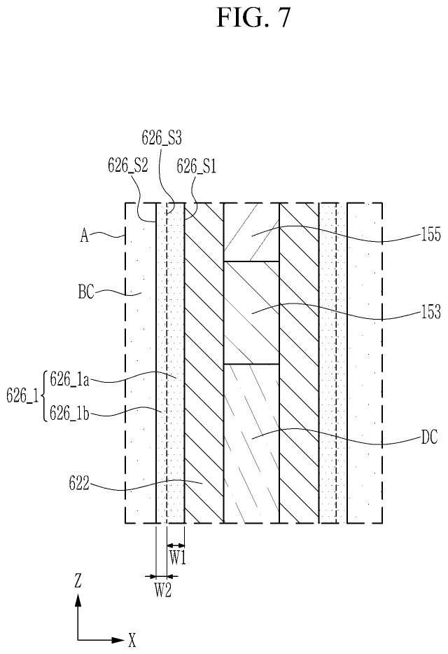

Hereinafter, another embodiment of the semiconductor device will be described with reference to FIGS. 7 to 16. In the following embodiment, the same reference numeral refers to a component identical to that of the previously described embodiment, and a redundant description thereof will not be repeated or simplified, and differences between the following embodiment and the previously described embodiment will be mainly described.

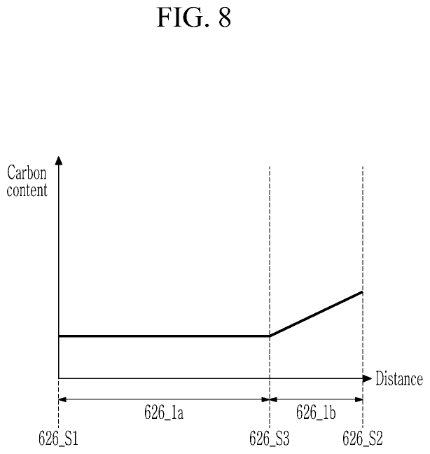

FIG. 7 is an enlarged cross-sectional view illustrating the enlarged region A of FIG. 2 according to another embodiment. FIGS. 8 to 10 are graphs schematically illustrating the carbon content according to a position within the third spacer according to an embodiment.

According to the embodiment shown in FIG. 7, unlike the embodiment shown in FIG. 5, a third spacer 626_1 may include a first region 626_1a and a second region 626_1b having different carbon contents. In addition, the third spacer 626_1 may further include a first interface 626_S3 between the first region 626_1a and the second region 626_1b. The term “first region 626_1a” refers to a region between the first surface 626_S1 and the first interface 626_S3, and the term “second region 626_1b” refers to a region between the first interface 626_S3 and the second surface 626_S2.

Specifically, the third spacer 626_1 may include the first region 626_1a that is adjacent to the bit line BL and may have a first carbon content. The second region 626_1b may be adjacent to the buried contact BC and may have a second carbon content that is higher than the first carbon content. The second region 626_1b of the third spacer 626_1 may be a region remaining at an outermost side of the third spacer 626_1 after the third spacer 626_1 is etched in a process step of etching the third spacer 626_1 to be described later.

The first region 626_1a of the third spacer 626_1 may have a first width W1 in the first direction (X direction), and the second region 626_1b may have a second width W1 in the first direction (X direction).

In an embodiment, the first width W1 may be greater than the second width W2. This is because a width of the second region 626_1b in the first direction (X direction) is reduced as the second region 626_1b disposed at an outermost side of the third spacer 626_1 is etched in the process of etching the third spacer 626_1 to be described later. However, a relationship between the first width W1 and the second width W2 is not limited thereto, and may vary depending on a distribution of a content of carbon included in the third spacer 626_1, a margin in a process, or the like. For example, in an embodiment, the first width W1 and the second width W2 may be substantially the same or the first width W1 may be smaller than the second width W2.

Referring further to FIG. 8 together with FIG. 7, the first region 626_1a of the third spacer 626_1 may have a constant first carbon content regardless of a position within the first region 626_1a, and the second region 626_1b may have a second carbon content that increases from the first interface 626_S3 between the first region 626_1a and the second region 626_1b to the second surface 626_S2 of the third spacer 626_1 and is higher than the first carbon content. The first carbon content and the second carbon content may be substantially the same at the first interface 626_S3 between the first region 626_1a and the second region 626_1b. However, the disclosure is not limited thereto, and the first carbon content and the second carbon content may be different from each other at the first interface 626_S3 between the first region 626_1a and the second region 626_1b.

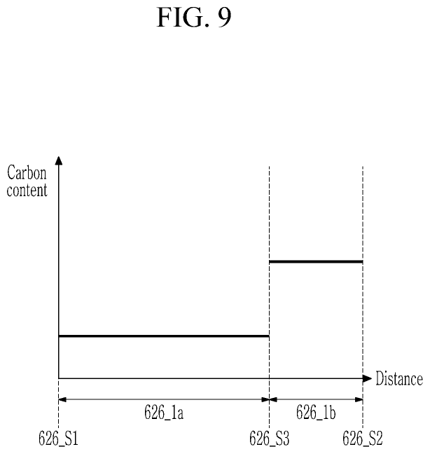

Referring to FIG. 9 together with FIG. 7, the first region 626_1a of the third spacer 626_1 may have a constant first carbon content regardless of a position within the first region 626_1. The second region 626_1b may have a second carbon content that is higher than the first carbon content and is constant regardless of a position within the second region 626_1b. Unlike the embodiment shown in FIG. 8, in the embodiment, the first carbon content and the second carbon content may be different at the first interface 626_S3 between the first region 626_1a and the second region 626_1b.

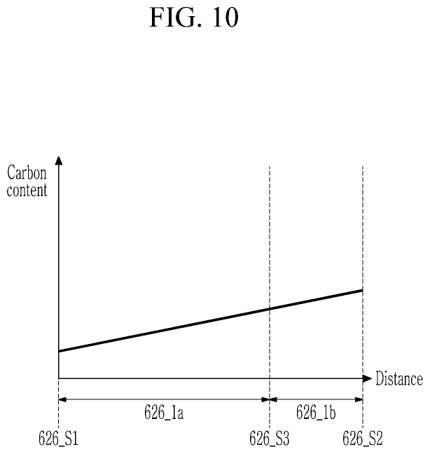

Referring further to FIG. 10 together with FIG. 7, the first region 626_1a of the third spacer 626_1 may have a first carbon content that increases from the first surface 626_S1 to the first interface 626_S3 between the first region 626_1a and the second region 626_1b, and the second region 626_1b may have a second carbon content that increases from the first interface 626_S3 between the first region 626_1a and the second region 626_1b to the second surface 626_S2 of the third spacer 626_1 and is higher than the first carbon content. That is, a carbon content within the third spacer 626 according to the embodiment may continuously increase from the first surface 626_S1 to the second surface 626_S2. The first carbon content and the second carbon content may be substantially the same at the first interface 626_S3 between the first region 626_1a and the second region 626_1b.

Although it is illustrated that the carbon content is constantly increased within the second region 626_1b of FIG. 8 and the third spacer 626_1 of FIG. 10, the disclosure is not limited thereto. For example, the carbon content within the second region 626_1b of FIG. 8 may increase from the first interface 626_S3 between the first region 626_1a and the second region 626_1b to the second surface 626_S2, but the increase may be decreased or may be increased. In addition, the carbon content within the third spacer 626_1 of FIG. 10 may increase from the first surface 626_S1 to the second surface 626_S2, but the increase may be less or more.

As described above, having various carbon content distributions within the third spacer 626_1 may be due to a process step of depositing the third spacer 626_1. Accordingly, a carbon content gradient within the third spacer 626_1 is not limited to the embodiments of FIGS. 8 to 10, and may be variously changed.

In an embodiment, the first carbon content may be about 5 at % or less, and the second carbon content may be about 5 at % or more and about 10 at % or less. However, the first carbon content and the second carbon content are not limited to the above numerical ranges, and may be variously changed.

When a carbon content of the third spacer 626 decreases, a dielectric constant of the third spacer 626 may decrease. That is, the dielectric constant of the third spacer 626 may change depending on a composition of a material included in the third spacer 626, and when the third spacer 626 has a low carbon content of about 5 at % or less, the third spacer 626 may have a low dielectric constant.

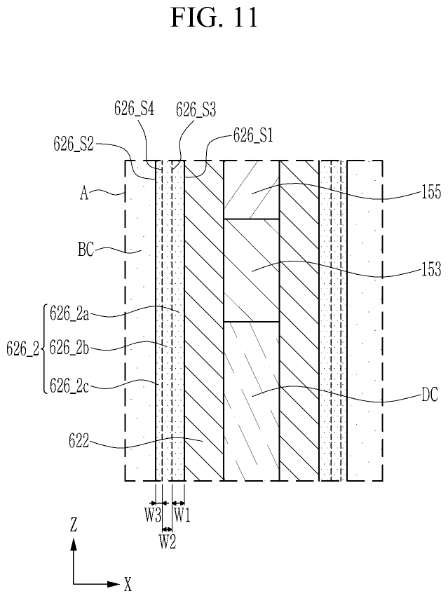

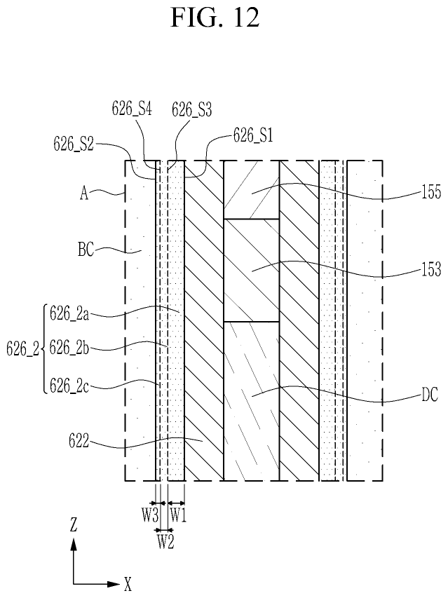

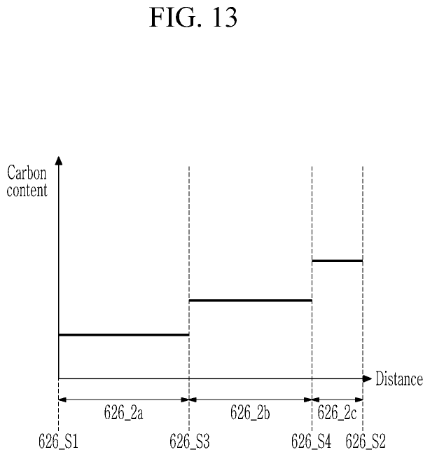

FIGS. 11 and 12 are enlarged cross-sectional views illustrating the enlarged region A of FIG. 2 according to another embodiment. FIGS. 13 to 16 are graphs schematically illustrating the carbon content according to a position within the third spacer according to an embodiment.

According to the embodiment shown in FIGS. 11 and 12, unlike the embodiment shown in FIG. 7, a third spacer 626_2 may further include a third region 626_2c that has a higher carbon content than the first region 626_1a and the second region 626_1b and is disposed outside the second region 626_1b.

In addition, the third spacer 626_2 may include a first interface 626_S3 between a first region 626_2a and a second region 626_2b and a second interface 626_S4 between the second region 626_2b and the third region 626_2c. The term “first region 626_2a” refers to a region between the first surface 626_S1 and the first interface 626_S3, the term “second region 626_1b” refers to a region between the first interface 626_S3 and the second interface 626_S4, and the term “third region 626_2c” refers to a region between the second interface 626_S4 and the second surface 626_S2.

The third region 626_2c of the third spacer 626_2 may be a region remaining at an outermost side of the third spacer 626_2 after the third spacer 626_2 is etched in a process step of etching the third spacer 626_2 that will be described later.

The first region 626_2a of the third spacer 626_2 may have a first width W1 in the first direction (X direction), the second region 626_2b may have a second width W2 in the first direction (X direction), and the third region 626_2c may have a third width W3 in the first direction (X direction).

In an embodiment, the first width W1 may be substantially equal to the second width W2, and the third width W3 may be smaller than the first and second widths W1 and W2. This is because a width of the third spacer 626_2c in the first direction (X direction) is reduced as the third region 626_2c disposed at the outermost side of the third spacer 626_2 is etched in the process of etching the third spacer 626_2 to be described later. However, a relationship between the first width W1, the second width W2, and the third width W3 is not limited thereto, and may vary depending on a distribution of a content of carbon included in the third spacer 626_2, a margin in a process, or the like.

As shown in the embodiment shown in FIG. 12, the first width W1 may be greater than the second width W2 and the third width W3, and the second width W2 may be greater than the third width W3. In addition, a sum of the second width W2 and the third width W3 may be less than the first width W1. For example, a sum of the second width W2 and the third width W3 may be less than or equal to about 30% of the first width W1.

Referring further to FIG. 13 together with FIG. 11, each of the first region 626_2a, the second region 626_2b, and the third region 626_2c of the third spacer 626_2 may have a constant carbon content regardless of a position within each of the first region 626_2a, the second region 626_2b, and the third region 626_2c. That is, the first region 626_2a may have a constant first carbon content regardless of a position within the first region 626_2a. The second region 626_2b may have a second carbon content that is higher than the first carbon content and is constant regardless of a position within the second region 626_2b. The third region 626_2c may have a third carbon content that is higher than the second carbon content and is constant regardless of a position within the third region 626_2c.

In FIG. 13, the first carbon content and the second carbon content may be different at the first interface 626_S3, and the second carbon content and the third carbon content may be different at the second interface 626_S4.

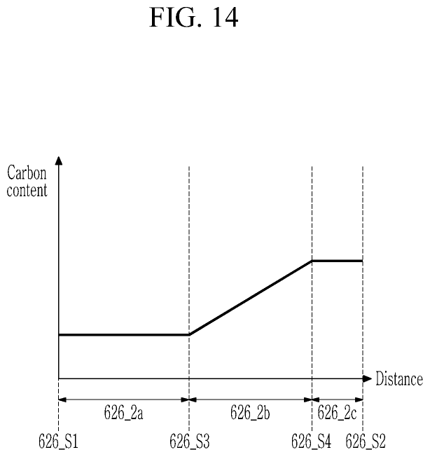

Referring further to FIG. 14 together with FIG. 11, the first region 626_2a of the third spacer 626_2 may have a constant first carbon content regardless of a position within the first region 626_2a, the second region 626_2b may have a second carbon content that increases from the first interface 626_S3 to a second surface 626_S4 and is higher than the first carbon content. The third region 626_2c may have a third carbon content that increases from the second interface 626_S4 to the second surface 626_S2 and is higher than the second carbon content. In FIG. 14, the first carbon content and the second carbon content may be substantially the same at the first interface 626_S3, and the second carbon content and the third carbon content may be substantially the same at the second interface 626_S4.

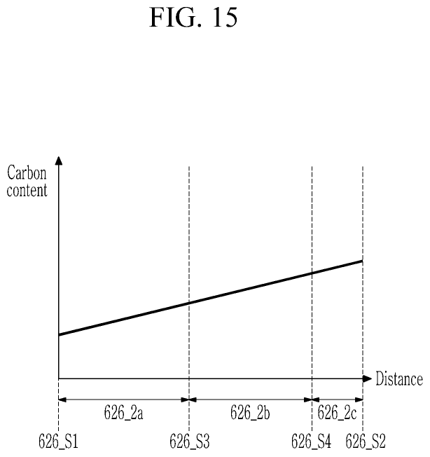

Referring further to FIG. 15 together with FIG. 11, the first region 626_2a of the third spacer 626_2 may have a first carbon content that increases from the first surface 626_S1 to the first interface 626_S3, the second region 626_2b may have a second carbon content that increases from the first interface 626_S3 to the second interface 626_S4 and is higher than the first carbon content, and the third region 626_2c may have a third carbon content that increases from the second interface 626_S4 to the second surface 626_S2 and is higher than the second carbon content.

That is, the carbon content within the third spacer 626_2 shown in FIG. 15 may continuously increase from the first surface 626_S1 to the second surface 626_S2. In addition, in FIG. 15, the first carbon content and the second carbon content may be substantially the same at the first interface 626_S3, and the second carbon content and the third carbon content may be substantially the same at the second interface 626_S4. However, the disclosure is not limited thereto, and the first carbon content and the second carbon content may be different from each other at the first interface 626_S3, and the second carbon content and the third carbon content may be different from each other at the second interface 626_S4.

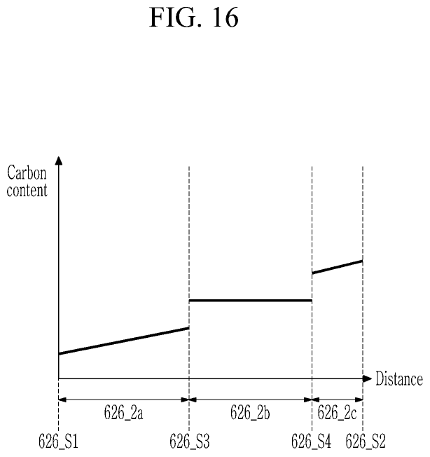

Referring further to FIG. 16 together with FIG. 11, the first region 626_2a of the third spacer 626_2 may have a first carbon content that increases from the first surface 626_S1 to the first interface 626_S3. The second region 626_2b may have a second carbon content that is higher than the first carbon content and is constant regardless of a position within the second region 626_2b. The third region 626_2c may have a third carbon content that increases from the second interface 626_S4 to the second surface 626_S2 and is higher than the second carbon content. In this case, the first carbon content and the second carbon content may be substantially the same at the first interface 626_S3, and the second carbon content and the third carbon content may be substantially the same at the second interface 626_S4.

The carbon content is illustrated to be constantly increased within the second region 626_2b of FIG. 14, the third spacer 626_2 of FIG. 15, and the first region 626_2a and the third region 626_2c of FIG. 16, but the disclosure is not limited thereto. For example, the carbon content in each of the first region 626_2a and the third region 626_2c of FIG. 16 may increase from the first surface 626_S1 to the first interface 626_S3 and may increase from the second interface 626_S4 to the second surface 626_S2, but the increase may be less or more. As another example, the increase in the carbon content in each of the first region 626_2a and the third region 626_2c of FIG. 16 may be different.

As described above, having various carbon content distributions within the third spacer 626_2 may be due to a process step of depositing the third spacer 626_2. Accordingly, a carbon content gradient within the third spacer 626_1 is not limited to the embodiments of FIGS. 13 to 16, and may be variously changed.

In an embodiment, the first carbon content may be about 5 at % or less, the second carbon content may be about 5 at % or more and about 10 at % or less, and the third carbon content may be about 10 at % or more and about 20 at % or less. However, the first carbon content, the second carbon content, and the third carbon content are not limited to the above numerical ranges, and may be variously changed.

According to the embodiments illustrated in FIGS. 7 to 16, the third spacers 626_1 and 626_2 may include regions having different carbon contents so that an electrical characteristic and productivity of the semiconductor device is improved.

That is, as the third spacers 626_1 and 626_2 have distributions in which the carbon content increases toward the outside, outer sides of the third spacers 626_1 and 626_2 having high carbon contents may have excellent etching resistance due to a low etching rate. Accordingly, in a process step of performing wet etching of the third spacers 626_1 and 626_2, the number of process steps may be reduced compared with a method of forming a plurality of spacers, leakage current may be reduced by preventing thicknesses of the third spacers 626_1 and 626_2 from becoming too thin due to excessive etching, and a short circuit between wires in a subsequent process may be prevented.

In addition, as the first regions 626_1a and 626_2a having low carbon contents remain inside the third spacers 626_1 and 626_2 adjacent to the bit line BL after the wet etching process, the third spacers 626_1 and 626_2 may have low dielectric constants. Accordingly, an electrical characteristic may be improved by reducing capacitance between the bit line BL and the buried contact BC with the third spacers 626_1 and 626_2 interposed and overlapped between the bit line BL and the buried contact BC.

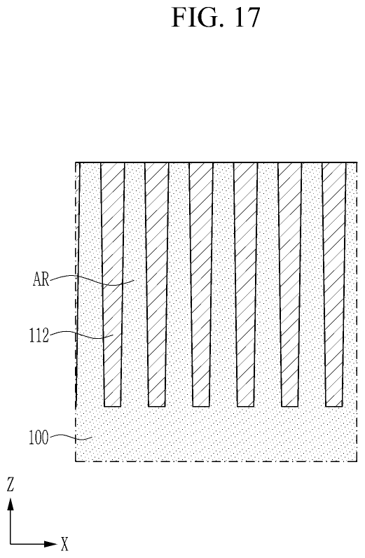

Hereinafter, a method for manufacturing the semiconductor device will be described with reference to FIGS. 17 to 33. The same configurations described above will be referred to by the same reference numerals, and redundant description will not be repeated or simplified, and a difference will be mainly described.

FIGS. 17 to 25 are cross-sectional views illustrating the method for manufacturing the semiconductor device according to an embodiment.

First, referring to FIG. 17, trenches for isolating a plurality of elements may be formed in the substrate 100, and the element isolation layer 112 may be formed to fill the trench. The plurality of active regions AR may be defined by element isolation layers 112. The plurality of active regions AR may be disposed within the substrate 100, and the plurality of active regions AR may be separated from each other by the element isolation layer 112. The element isolation layer 112 may be positioned at both sides of each active region AR. The active region AR may have a rod shape extending along the fourth direction DR4 oblique with respect to the first direction (X direction) and the second direction (Y direction) on a plane.

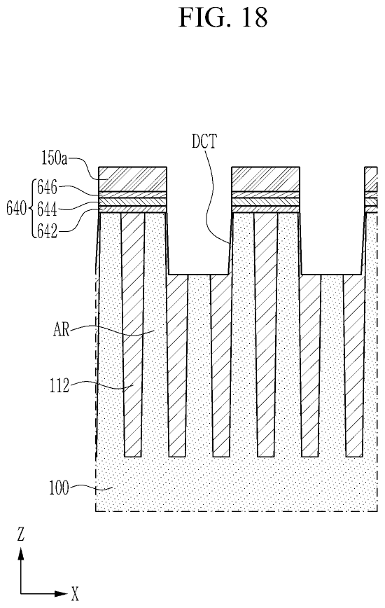

Subsequently, referring to FIG. 18, the first insulating layer 642, the second insulating layer 644, the third insulating layer 646, and a first material layer 150a may be sequentially stacked on the substrate 100, and then the first insulating layer 642, the second insulating layer 644, the third insulating layer 646, and a first material layer 150a sequentially stacked on the substrate 100 may be patterned to form the direct contact trench DCT.

The first insulating layer 642, the second insulating layer 644, and the third insulating layer 646 may form the insulating layer 640. However, a structure of the insulating layer 640 is not limited thereto, and may be formed of a single layer, a double layer, or four or more insulating layers.

Each of the first insulating layer 642, the second insulating layer 644, and the third insulating layer 646 may be made of an insulating material. For example, the first insulating layer 642 may include a silicon oxide. The second insulating layer 644 may include a material having an etching selectivity different from that of the first insulating layer 642. For example, the second insulating layer 644 may include a silicon nitride. The third insulating layer 646 may include, for example, a silicon oxide or a silicon nitride. However, a material or the like of the insulating layer 640 is not limited thereto, and may be variously changed.

The first material layer 150a may include a conductive material. For example, the first material layer 150a may include a polysilicon doped with an impurity or a metal such as W, Mo, Au, Cu, Al, Ni, Co, or the like.

The first material layer 150a, the third insulating layer 646, the second insulating layer 644, and the first insulating layer 642 may be patterned to form the direct contact trench DCT that exposes at least a portion of the active region AR. For example, a hard mask layer may be formed above or on the first material layer 150a.

A hard mask pattern may be formed by patterning the hard mask layer using a photo and etching process. The first material layer 150a, the third insulating layer 646, the second insulating layer 644, and the first insulating layer 642 may be sequentially etched using the hard mask pattern. When the first insulating layer 642 is etched, upper surfaces of the active region AR of the substrate 100 and the element isolation layer 112 may be exposed.

Subsequently, the active region AR and the element isolation layer 112 may be etched to form the direct contact trench DCT. In this case, the active region AR may be disposed at an approximately central portion of the direct contact trench DCT. The active region AR and the element isolation layer 112 may constitute a bottom surface of the direct contact trench DCT. The element isolation layer 112, the insulating layer 640, and the first material layer 150a may constitute a sidewall of the direct contact trench DCT. The direct contact trench DCT may have a shape in which a width gradually decreases toward the bottom surface. However, a formation method, a shape, or the like of the direct contact trench DCT is not limited thereto, and may be variously changed.

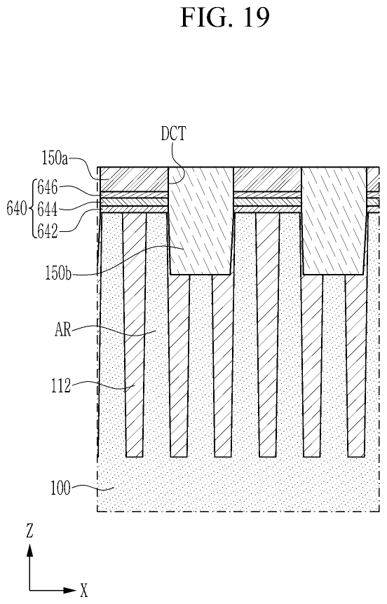

Subsequently, referring to FIG. 19, a second material layer 150b may be formed within the direct contact trench DCT. A lower surface of the second material layer 150b may contact the active region AR. A side surface of the second material layer 150b may contact the first material layer 150a. An upper surface of the second material layer 150b and an upper surface of the first material layer 150a may be flat. That is, the upper surface of the second material layer 150b and the upper surface of the first material layer 150a may be disposed at substantially the same level.

When a conductive material is deposited in a state where the direct contact trench DCT is formed in the substrate 100, the second material layer 150b may be formed on the first material layer 150a. In this case, the second material layer 150b may be formed to fill the inside of the direct contact trench DCT.

Subsequently, when a planarization process is performed until the upper surface of the first material layer 150a is exposed, the upper surfaces of the first material layer 150a and the second material layer 150b may be planarized.

The second material layer 150b may include a conductive material. For example, the second material layer 150b may include a polysilicon doped with an impurity or a metal such as W, Mo, Au, Cu, Al, Ni, Co, or the like. The second material layer 150b may be made of the same material as the first material layer 150a. A boundary between the first material layer 150a and the second material layer 150b may not be distinct.

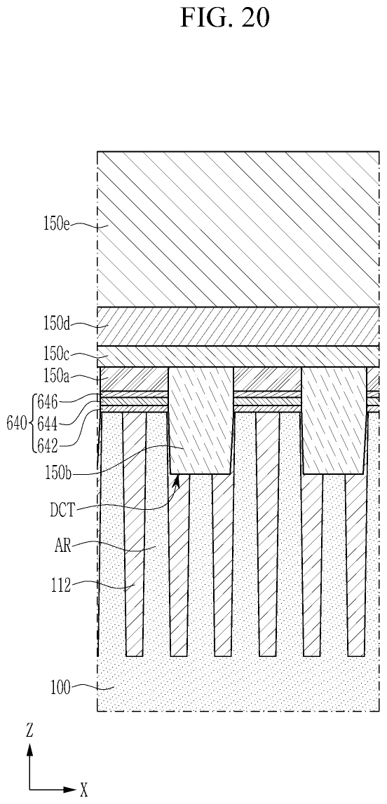

Next, referring to FIG. 20, a third material layer 150c, a fourth material layer 150d, and a fifth material layer 150e may be sequentially stacked on the first material layer 150a and the second material layer 150b. A lower surface of the third material layer 150c may contact the first material layer 150a and the second material layer 150b. The third material layer 150c may be disposed between the first material layer 150a and the fourth material layer 150d, and may be disposed between the second material layer 150b and the fourth material layer 150d. An upper surface of the third material layer 150c may contact the fourth material layer 150d.

The third material layer 150c may include a conductive material. For example, the third material layer 150c may include a metal such as Ti, Ta, or the like and/or a metal nitride such as TiN, TaN, or the like. The fourth material layer 150d may include a conductive material. For example, the fourth material layer 150d may include a metal such as W, Mo, Au, Cu, Al, Ni, or Co. The fifth material layer 150e may include an insulating material. For example, the fifth material layer 150e may include a silicon nitride. However, the materials of the third material layer 150c, the fourth material layer 150d, and the fifth material layer 150e are not limited thereto, and may be variously changed.

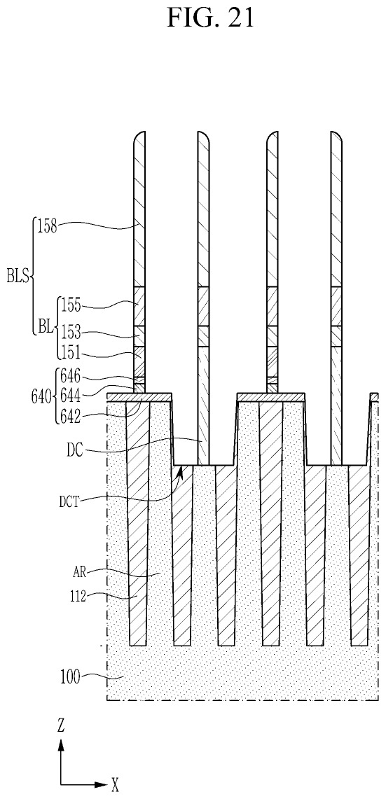

Next, referring to FIG. 21, the fifth material layer 150e, the fourth material layer 150d, the third material layer 150c, the second material layer 150b, and the first material layer 150a may be patterned. That is, a photo and etching process may be performed to remove at least a portion of the fifth material layer 150e, the fourth material layer 150d, the third material layer 150c, the second material layer 150b, and the first material layer 150a. Through the patterning process, the direct contact DC and the bit line structure BLS may be formed.

For example, the direct contact DC may be formed by patterning the second material layer 150b. The direct contact DC may be disposed within the direct contact trench DCT. The direct contact DC may be disposed at an approximately central portion of the direct contact trench DCT. The direct contact DC may be disposed on the active region AR, and may be connected to the active region AR.

The bit line structure BLS may be formed by patterning the first material layer 150a, the third material layer 150c, the fourth material layer 150d, and the fifth material layer 150e.

The bit line structure BLS may include the bit line BL and the bit line capping layer 158.

The bit line capping layer 158 may be formed by patterning the fifth material layer 150e. The bit line BL may include the first conductive layer 151, the second conductive layer 153, and the third conductive layer 155.

The first material layer 150a may be patterned to form the first conductive layer 151 of the bit line BL, the third material layer 150c may be patterned to form the second conductive layer 153 of the bit line BL, and the fourth material layer 150d may be patterned to form the third conductive layer 155 of the bit line BL.

The second conductive layer 153 may be disposed on the first conductive layer 151 of the bit line BL, the third conductive layer 155 may be disposed on the second conductive layer 153, and the bit line capping layer 158 may be disposed on the third conductive layer 155.

In addition, the second conductive layer 153 of the bit line BL may be disposed on an upper surface of the direct contact DC, and the first conductive layer 151 of the bit line BL may be disposed above or on a side surface of the direct contact DC.

The second insulating layer 644 and the third insulating layer 646 disposed below the second material layer 150b may be exposed to the outside and may be etched as the second material layer 150b is removed. The first insulating layer 642 disposed below the second insulating layer 644 may include a material having a different etching selectivity from that of the second insulating layer 644.

Accordingly, even if the first insulating layer 642 is exposed as the second insulating layer 644 is removed, the first insulating layer 642 may hardly be etched. However, at least a portion of the first insulating layer 642 may be etched to reduce a thickness.

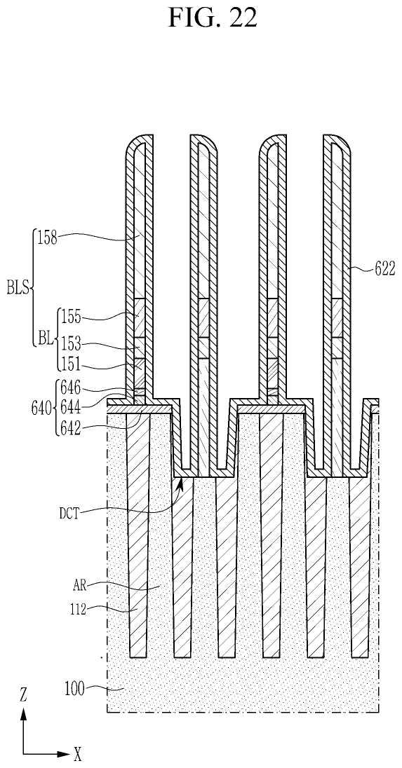

Next, referring to FIG. 22, the first spacer 622 may be formed on the bit line structure BLS by using an insulating material. The first spacer 622 may be formed on the bit line structure BLS to have a conformal shape.

The first spacer 622 may cover side surfaces of the bit line structure BLS and the direct contact DC. The first spacer 622 may cover side surfaces of the second insulating layer 644 and the third insulating layer 646, and may cover upper and side surfaces of the first insulating layer 642. The first spacer 622 may cover a bottom surface and a sidewall of the direct contact trench DCT.

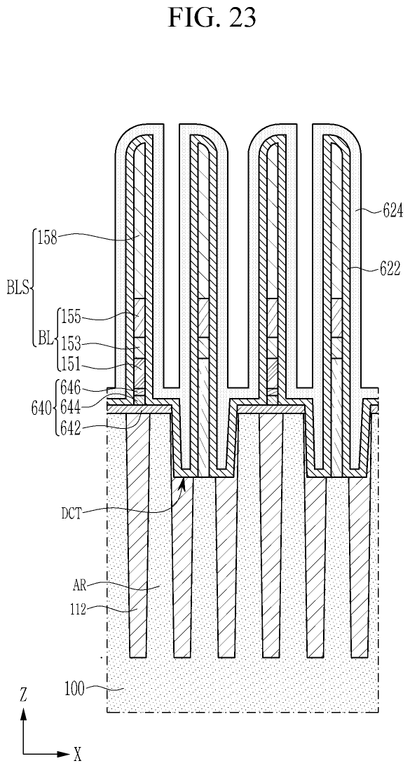

Next, referring to FIG. 23, the second spacer 624 may be formed on the first spacer 622 using an insulating material. The second spacer 624 may be formed on the first spacer 622 to have a conformal shape. A thickness of the second spacer 624 may be greater than a thickness of the first spacer 622, but the disclosure is not limited thereto. The second spacer 624 may be formed to fill the direct contact trench DCT.

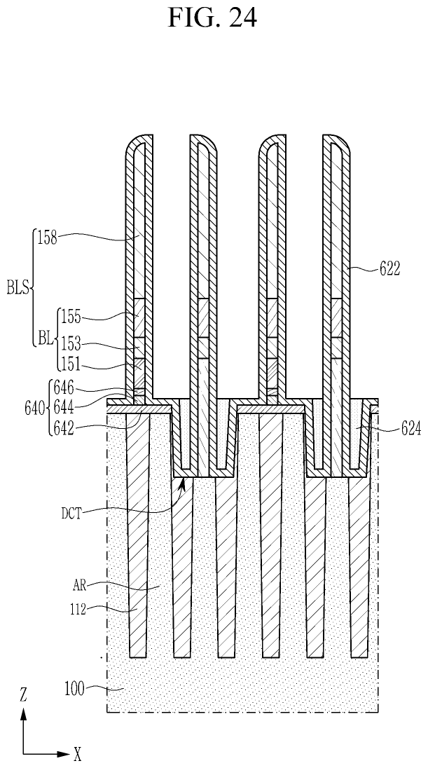

Next, referring to FIG. 24, the second spacer 624 may be patterned to leave a portion of the second spacer 624 disposed within the direct contact trench DCT, and the remaining portion of the second spacer 624 may be removed. A portion of the second spacer 624 covering the bit line structure BLS may be removed.

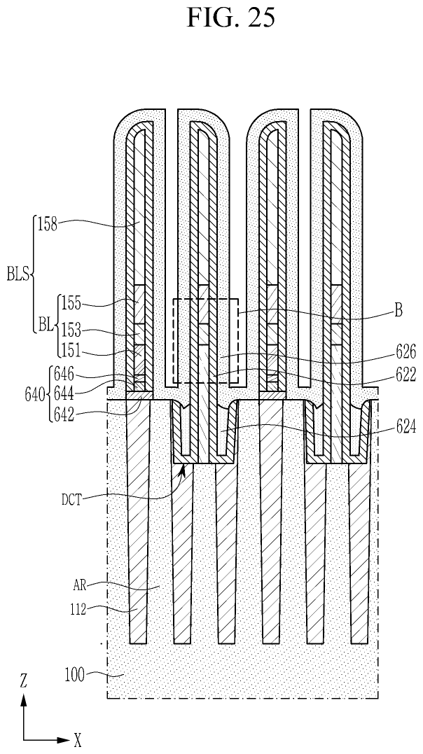

Next, referring to FIG. 25, the third spacer 626 may be formed on the first spacer 622 and the second spacer 624 using an insulating material. The insulating material may include at least one of SiOCN, SiOC, SiOCF, and a combination thereof. However, the insulating material included in the third spacer 626 is not limited thereto, and may be variously changed. Hereinafter, description will be made on the basis that the third spacer 626 includes SiOCN.

The third spacer 626 may be formed on the first spacer 622 and the second spacer 624 to have a conformal shape. A thickness of the third spacer 626 may be thicker than thicknesses of the first spacer 622 and the second spacer 624, but the disclosure is not limited thereto.

The first spacer 622, the second spacer 624, and the third spacer 626 may constitute the spacer structure 620.

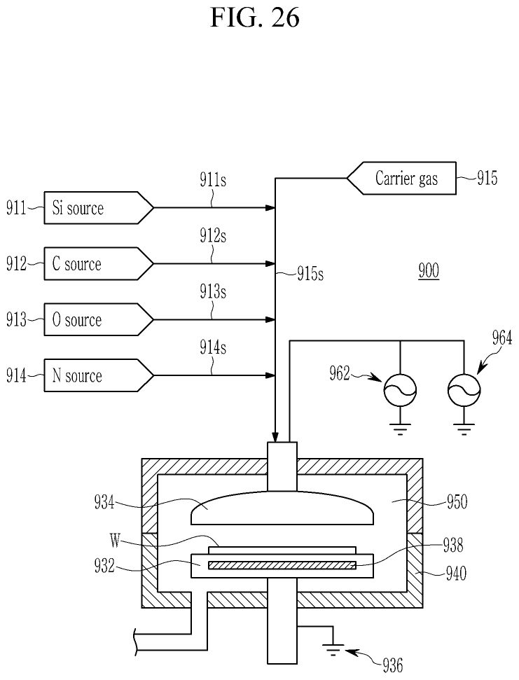

FIG. 26 is a conceptual view schematically illustrating equipment for forming the third spacer according to an embodiment.

Referring to FIG. 26, a pair of conductive flat electrodes 932 and 934 that face each other and extend in parallel may be disposed within a reaction space 950 that is inside a reaction chamber 940. An HRF power 962 of 13.56 MHz or 27 MHz (and an LRF power 964 of 5 MHz or less (400 kHz to 500 kHz) as necessary) may be applied to one of the pair of conductive flat electrodes 932 and 934 and the other electrode of the pair of conductive flat electrodes 932 and 934 may be electrically grounded to a ground 936, so that a plasma is excited between the pair of conductive flat electrodes 932 and 934.

A lower electrode 932 of the pair of conductive flat electrodes 932 and 934 may also serve as a support for supporting a substrate W, and a temperature controller 938 may be included within the lower electrode 932 to maintain a temperature of the substrate W at a desired temperature.

An upper electrode 934 of the pair of conductive flat electrodes 932 and 934 may also serve as a shower head in addition to serving as an electrode. In an embodiment, various gases including sources may be introduced into the reaction space 950 through the upper electrode 934. In an embodiment, some gases may be introduced into the reaction space 950 through their own conduits.

A carrier gas 915 may serve to transport the sources and/or reactants to the reaction space 950. In an embodiment, the carrier gas 915 may serve to purge an unreacted material or by-products inside the reaction space 950.

For example, the carrier gas 915 may be an inert gas such as helium (He) or neon (Ne), or a gas with extremely low activity such as nitrogen (N₂) or carbon dioxide (CO₂). However, the carrier gas 915 is not limited thereto, and may be variously changed.

A Si source 911 may be introduced into the reaction space 950 through a Si source supply line 911s. In this case, the Si source supply line 911s may be joined to a carrier gas supply line 915s.

FIG. 26 illustrates that the supply line 915s of the carrier gas 915 is connected to supply lines 911s, 912s, 913s, and 914s of the Si source 911, a C source 912, an O source 913, and an N source 914. In some implementations, the supply lines may be directly connected to the reaction chamber 940 without being independently connected to the supply line of the carrier gas 915. In particular, in a case where there is a concern that a material remaining within a conduit between supply periods (or supply cycles) could react with a material supplied in a next process, the supply lines may not be joined to the supply line of the carrier gas 915.

For example, the Si source 911 may be a silane-based silicon precursor substituted with a halogen such as monofluorosilane (SiFH₃), difluorosilane (SiF₂H₂), trifluorosilane (SiF₃H), tetrafluorosilane (SiF₄), monofluorodisilane (Si₂FH₅), difluorodisilane (Si₂F₂H₄), trifluorodisilane (Si₂F₃H₃), tetrafluorodisilane (Si₂F₄H₂), pentafluorodisilane (Si₂F₅H), hexafluorodisilane (Si₂F₆), monochlorosilane (SiClH₃), dichlorosilane (SiCl₂H₂), trichlorosilane (SiCl₃H), tetrachlorosilane (SiCl₄), monochlorodisilane (Si₂ClH₅), dichlorodisilane (Si₂Cl₂H₄), trichlorodisilane (Si₂Cl₃H₃), tetrachlorodisilane (Si₂Cl₄H₂), pentachlorodisilane (Si₂Cl₅H), hexachlorodisilane (Si₂Cl₆), monobromosilane (SiBrH₃), dibromosilane (SiBr₂H₂), tribromosilane (SiBr₃H), tetrabromosilane (SiBr₄), monobromodisilane (Si₂BrH₅), dibromodisilane (Si₂Br₂H₄), tribromodisilane (Si₂Br₃H₃), tetrabromodisilane (Si₂Br₄H₂), pentabromodisilane (Si₂BrsH), hexabromodisilane (Si₂Br₆), monoiodosilane (SiIH₃), diiodosilane (SiI₂H₂), triiodosilane (SiI₃H), tetraiodosilane (SiI₄), monoiododisilane (Si₂IH₅), diiododisilane (Si₂I₂H₄), triiododisilane (Si₂I₃H₃), tetraiododisilane (Si₂I+H₂), pentaiododisilane (Si₂I₅H), hexaiododisilane (Si₂I₆), or the like. However, the Si source 911 is not limited thereto, and may be variously changed.

For example, the C source 912 may be one or more selected from the group consisting of an alkane having 1 to 10 carbon atoms, an alkene having 2 to 10 carbon atoms, an alkylamine having 1 to 15 carbon atoms, a nitrogen-containing heterocyclic compound having 4 to 15 carbon atoms, an alkylsilane having 1 to 20 carbon atoms, an alkoxysilane having 1 to 20 carbon atoms, and an alkylsiloxane having 1 to 20 carbon atoms. However, the C source 912 is not limited thereto, and may be variously changed.

For example, the O source 913 may be O₃, H₂O (e.g., deionized water, purified water, and/or distilled water), O₂, NO₂, NO, N₂O, H₂O, carbon monoxide (CO), carbon dioxide (CO₂), alcohol, a metal alkoxide, Oz plasma, remote plasma O₂, N₂O plasma, H₂O plasma, or a combination thereof. However, the O source 913 is not limited thereto, and may be variously changed.

A material of the O source 913 may be introduced into the reaction space 950, or may be incidentally among another material used in a deposition process.

For example, the N source 914 may be N₂, NH₃, hydrazine (N₂H₄), monoalkylhydrazine, dialkylhydrazine, N₂ plasma, remote plasma N₂, or a combination thereof. However, the N source 914 is not limited thereto, and may be variously changed.

A material of the N source 914 may be introduced into the reaction space 950, or may be incidentally among another material used in a deposition process.

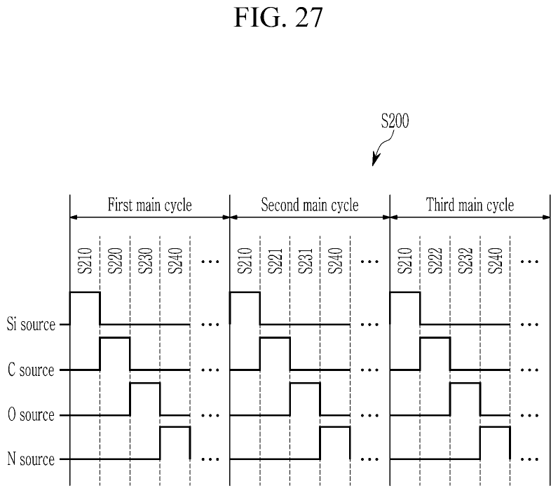

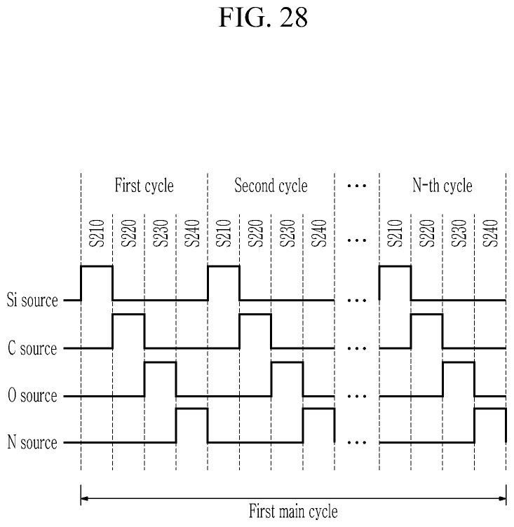

FIG. 27 is a timing diagram illustrating a supply cycle of the sources according to an embodiment. FIG. 28 is a timing diagram illustrating any one of supply cycles of the sources according to an embodiment.

Referring to FIG. 27, a process S200 of supplying a plurality of sources within the reaction chamber 940 of FIG. 26 to form the third spacer 626 of FIG. 25 may include a first main cycle, a second main cycle, and a third main cycle. The first main cycle, the second main cycle, and the third main cycle may be sequentially performed.

Each main cycle may include may include a sub-cycle including an Si source supply step S210, a C source supply step S220, S221, or S222, an O source supply step S230, S231, or S232, and an N source supply step S240 at least once.

For example, as shown in FIG. 28, in the first main cycle, a sub-cycle in which the Si source supply step S210, a first C source supply step S220, a first O source supply step S230, and the N source supply step S240 are sequentially performed may be repeated N times. That is, the sub-cycle may be repeated N times until a desired carbon content is formed at each region within the third spacer 626. Although FIG. 28 is described based on the first main cycle, the description of the first main cycle may be substantially equally applied to the second main cycle and the third main cycle.

In addition, although a purge process is not specified between supplies of source materials in FIGS. 27 and 28, a person skilled in the art will understand that a purge gas may be supplied between supplies of the source materials.

A method of depositing the third spacer 626 by sequentially supplying the Si source 911, the C source 912, the O source 913, and the N source 914 may be performed according to an atomic layer deposition (ALD) method. However, the disclosure is not limited thereto, and in an embodiment, the third spacer 626 may be deposited by a plasma-enhanced ALD (PEALD) method.

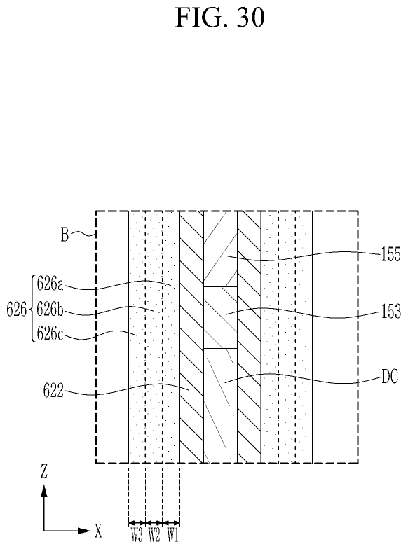

Specifically, the first main cycle corresponds to a cycle for forming a first region 626a of the third spacer 626 to be described later with reference to FIG. 30. The first region 626a of the third spacer 626 may be formed by repeating the sub-cycle including the Si source supply step S210, the first C source supply step S220, the first O source supply step S230, and the N source supply step S240 at least once N times.

In an embodiment, a progress time of the first C source supply step S220 may be substantially the same as a progress time of the first O source supply step S230. A quantity of flow of the C source introduced into the reaction space 950 in the first C source supply step S220 may be smaller than a quantity of flow of the O source introduced into the reaction space 950 in the first O source supply step S230.

Accordingly, the first region 626a of the third spacer 626 formed by the first main cycle may have a first carbon content. For example, the first carbon content may be about 5 at % or less. However, the first carbon content is not limited thereto, and may be variously changed.

The second main cycle corresponds to a cycle for forming a second region 626b of the third spacer 626 to be described later with reference to FIG. 30. The second region 626b of the third spacer 626 may be formed by repeating a sub-cycle including the Si source supply step S210, a second C source supply step S221, a second O source supply step S231, and the N source supply step S240 at least once N times.

In an embodiment, a progress time of the second C source supply step S221 may be substantially the same as a progress time of the second O source supply step S231. In addition, the progress time of the second C source supply step S221 and the progress time of the second O source supply step S231 may be substantially the same as the progress time of the first C source supply step S220 and the progress time of the first O source supply step S230.

A quantity of flow of the C source introduced into the reaction space 950 in the second C source supply step S221 may be greater than a quantity of flow of the C source introduced into the reaction space 950 in the first C source supply step S220. In addition, a quantity of flow of the O source introduced into the reaction space 950 in the second O source supply step S231 may be smaller than the quantity of flow of the O source introduced into the reaction space 950 in the first O source supply step S230.

Accordingly, the second region 626b of the third spacer 626 formed by the second main cycle may have a relatively higher second carbon content than that of the first region 626a. For example, the second carbon content may be about 5 at % or more and about 10 at % or less. However, the second carbon content is not limited thereto, and may be variously changed.

The third main cycle corresponds to a cycle for forming a third region 626c of the third spacer 626 to be described later with reference to FIG. 30. The third region 626c of the third spacer 626 may be formed by repeating a sub-cycle including the Si source supply step S210, a third C source supply step S222, a third O source supply step S232, and the N source supply step S240 at least once N times.

In an embodiment, a progress time of the third C source supply step S222 may be substantially the same as a progress time of the third O source supply step S232. In addition, the progress time of the third C source supply step S222 and the progress time of the third O source supply step S232 may be substantially the same as the progress time the second C source supply step S221 and the progress time of the second O source supply step S231.

A quantity of flow of the C source introduced into the reaction space 950 in the third C source supply step S222 may be greater than a quantity of flow of the C source introduced into the reaction space 950 in the second C source supply step S221. In addition, a quantity of flow of the O source introduced into the reaction space 950 in the third O source supply step S232 may be smaller than a quantity of flow of the O source introduced into the reaction space 950 in the second O source supply step S231.

Accordingly, the third region 626c of the third spacer 626 formed by the third main cycle may have a relatively higher third carbon content than those of the first region 626a and the second region 626b. For example, the third carbon content may be about 10 at % or more and 20% or less. However, the third carbon content is not limited thereto, and may be variously changed.

The number of sub-cycles constituting the above-described main cycles may be different from each other. However, the disclosure is not limited thereto, and in an embodiment, the sub-cycles constituting each main cycle may be performed the same number of times.

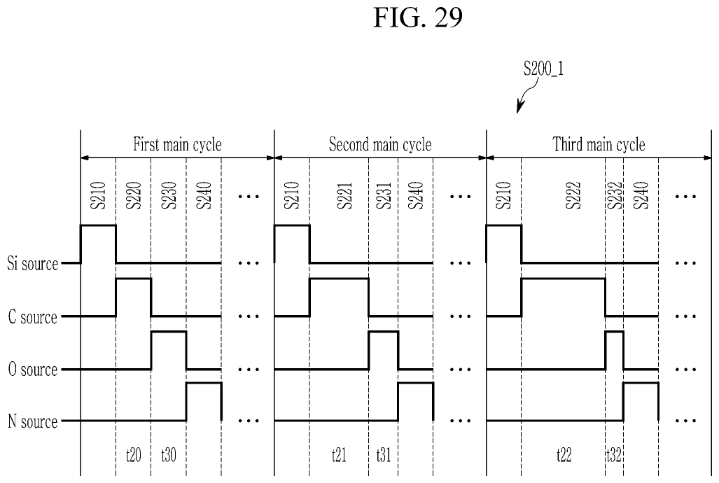

FIG. 29 is a timing diagram illustrating a supply cycle of the sources according to another embodiment.

Referring to FIG. 29, unlike the embodiment of FIG. 27, a quantity of flow of the C source introduced into the reaction space 950 in the C source supply step S220, S221, or S222 in each main cycle and a quantity of flow of the O source introduced into the reaction space 950 in the O source supply step S230, S231, or S232 in each main cycle may be substantially the same.

In addition, progress times of the C source supply steps S220, S221, and S222 in the main cycles may be different. In addition, progress times of the O source supply steps 230, S231, and S232 in the main cycles may be different.

Specifically, the progress time t20 of the first C source supply step S220 in the first main cycle may be shorter than the progress time t21 of the second C source supply step S221 in the second main cycle, and the progress time t21 of the second C source supply step S221 in the second main cycle may be shorter than the progress time t22 of the third C source supply step S222 in the third main cycle.

The progress time t30 of the first O source supply step S230 in the first main cycle may be longer than the progress time t31 of the second O source supply step S231 in the second main cycle, and the progress time t31 of the second O source supply step S231 may be longer than the progress time t32 of the third O source supply step S232 in the third main cycle.

Accordingly, the first region 626a, the second region 626b, and the third region 626c of the third spacer 626 to be described later with reference to FIG. 30 may be formed, and the third spacer 626 may have a carbon content increasing from the first region 626a to the third region 626c.

In FIG. 29, the quantity of flow of the C source introduced into the reaction space 950 in the C source supply step S220, S221, or S222 in each main cycle and the quantity of flow of the O source introduced into the reaction space 950 in the O source supply step S230, S231, or S232 in each main cycle may be substantially the same, the progress times of the C source supply steps S220, S221, and S222 may increase from the first main cycle to the third main cycle, and progress times of the O source supply steps S230, S231, and S232 may decrease from the first main cycle to the third main cycle. However, the disclosure is not limited thereto.

For example, at the same time as performing each main cycle according to the embodiment shown in FIG. 29, like the embodiment according to FIG. 27, quantities of flows of the C sources introduced into the reaction space 950 in the C source supply steps S220, S221, and S222 may increase from the first main cycle to the third main cycle, and quantities of flows of the O sources introduced into the reaction space 950 in the O source supply steps S230, S231, and S232 may decrease from the first main cycle to the third main cycle.

FIG. 30 is an enlarged view of a region B of FIG. 25.

Subsequently, referring to FIG. 30, the third spacer 626 including regions having different carbon contents may be formed through the process described above with reference to FIGS. 26 to 29.

The first region 626a of the third spacer 626 may have a first width W1 in the first direction (X direction), the second region 626b may have a second width W2 in the first direction (X direction), and the third region 626c may have a third width W3 in the first direction (X direction).

In an embodiment, the first width W1, the second width W2, and the third width W3 may be substantially the same. However, the disclosure is not limited thereto, and in an embodiment, at least one of the first width W1, the second width W2, and the third width W3 may be different. For example, the first width W1 and the third width W3 may be substantially the same, and the second width W2 may be smaller than the first width W1 and the third width W3.

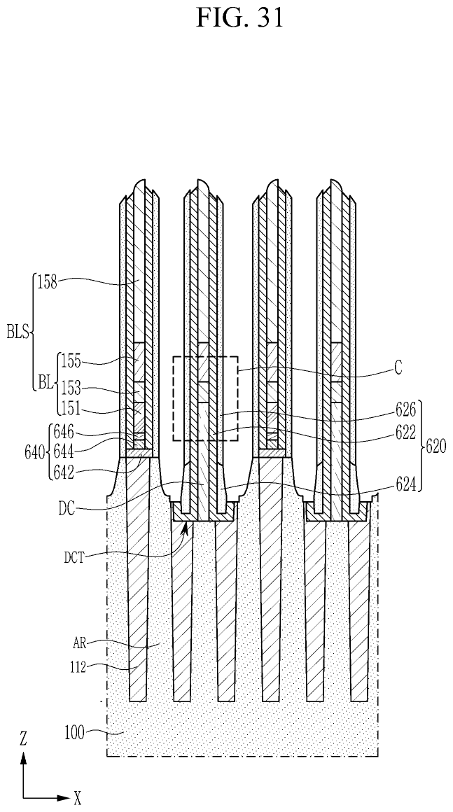

Since the third region 626c disposed at an outermost side of the third spacer 626 has a relatively high carbon content compared with the first region 626a and the second region 626b, the third region 626c may have excellent etching resistance in an etching process to be described later with reference to FIG. 31. Accordingly, the first region 626a may remain without being damaged by preventing a thickness of the third spacer 626 from becoming too thin. In an embodiment, at least a portion of not only the first region 626a but also the second region 626b or the third region 626c may remain without being removed.

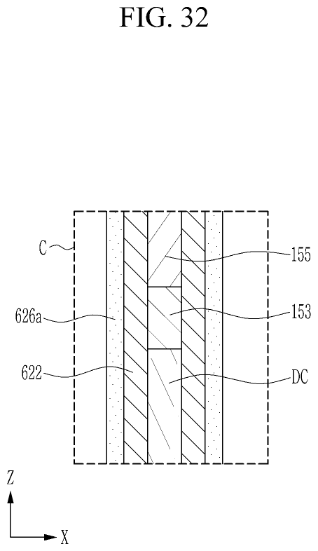

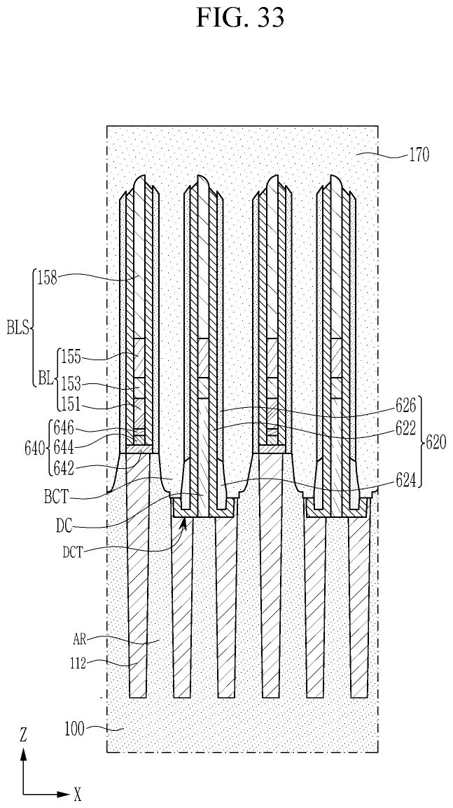

FIGS. 31 and 33 are cross-sectional views illustrating a method for manufacturing the semiconductor device according to an embodiment. FIG. 32 is an enlarged view of a region C of FIG. 31.

First, referring to FIG. 31, the third spacer 626 may be patterned. An upper surface of the bit line capping layer 158 may be exposed by removing the third spacer 626 disposed above the bit line structure BLS. The active region AR disposed between the bit line structures BLS may be exposed by removing the third spacer 626 disposed between the bit line structures BLS.

Subsequently, at least a portion of the active region AR may be removed through an etching process to form a buried contact trench BCT. In this case, at least a portion of the element isolation layer 112, the first spacer 622, and the second spacer 624 disposed around the active region AR may be removed together.

At least a portion of the bit line capping layer 158 may be removed together. In addition, at least a portion of the first spacer 622 and the third spacer 626 disposed around the bit line capping layer 158 may be removed together.

Subsequently, a conductive material layer 170 may be formed on the bit line structure BLS. The conductive material layer 170 may be formed between the bit line structures BLS. The buried contact trench BCT may be filled with the conductive material layer 170. Thus, the conductive material layer 170 may contact the active region AR.

The conductive material layer 170 may include a conductive material. For example, the conductive material layer 170 may include a polysilicon doped with an impurity, but the disclosure is not limited thereto.

Next, the conductive material layer 170 may be patterned to form the buried contact BC shown in FIG. 2. The buried contact BC may be electrically connected to the active region AR.

Subsequently, the landing pad LP connected to the buried contact BC may be formed, and the insulating pattern 660 separating the landing pads LP may be formed. A capacitor structure (not shown) may be further formed above or on the landing pad LP. The capacitor structure may be electrically connected to the active region AR through the landing pad LP and the buried contact BC.

By way of summation and review, a semiconductor device having an improved reliability and productivity electrical characteristic according to embodiments may be provided. Embodiments may also provide a bit line spacer having excellent etching resistance and an electrical characteristic and that may be disposed above or on a side surface of a bit line.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope of the present invention as set forth in the following claims.

What is claimed is:

1. A semiconductor device comprising:
a substrate including an active region defined by an element isolation layer;
a word line crossing the active region;
a bit line crossing the active region in a direction different from the word line;
a direct contact connecting between the active region and the bit line;
a buried contact connected to the active region; and
a bit line spacer that is disposed between the bit line and the buried contact and includes carbon,
wherein the bit line spacer includes a first region that is adjacent to the bit line and has a first carbon content and a second region that is adjacent to the buried contact and has a second carbon content that is higher than the first carbon content.

2. The semiconductor device as claimed in claim 1, wherein each of the first carbon content and the second carbon content is about 5 at % or less.

3. The semiconductor device as claimed in claim 1, wherein the first carbon content is about 5 at % or less, and the second carbon content is about 5 at % or more to about 10 at % or less.

4. The semiconductor device as claimed in claim 3, wherein a width of the first region is different from a width of the second region.

5. The semiconductor device as claimed in claim 1, wherein the bit line spacer further includes a third region that has a third carbon content that is greater than the first carbon content and the second carbon content, and the second region is disposed between the first region and the third region.

6. The semiconductor device as claimed in claim 5, wherein the bit line spacer includes at least one of SiOCN, SiOC, and SiOCF.

7. The semiconductor device as claimed in claim 5, wherein the first carbon content is about 5 at % or less, the second carbon content is about 5 at % or more and about 10 at % or less, and the third carbon content is about 10 at % or more to about 20 at % or less.

8. The semiconductor device as claimed in claim 5, wherein the first region has a first width, the second region has a second width, the third region has a third width, and at least one of the first width, the second width, and the third width is different.

9. The semiconductor device as claimed in claim 8, wherein the third width is smaller than the first width and the second width.

10. The semiconductor device as claimed in claim 5, wherein the first carbon content within the first region and the third carbon content within the third region are constant, and the second carbon content within the second region increases from an interface between the first region and the second region to an interface between the second region and the third region.

11. The semiconductor device as claimed in claim 5, wherein the bit line spacer includes a first surface adjacent to the bit line and a second surface adjacent to the buried contact, the first carbon content within the first region increases from the first surface to an interface between the first region and the second region, the second carbon content within the second region is constant, and the third carbon content within the third region increases from an interface between the second region and the third region to the second surface.

12. The semiconductor device as claimed in claim 5, wherein the bit line spacer includes a first surface adjacent to the bit line and a second surface adjacent to the buried contact, the first carbon content within the first region increases from the first surface to an interface between the first region and the second region, the second carbon content within the second region increases from the interface between the first region and the second region to an interface between the second region and the third region, the third carbon content within the third region increases from the interface between the second region and the third region to the second surface, and the first carbon content, the second carbon content, and the third carbon content continuously increase.

13. The semiconductor device as claimed in claim 5, wherein the first carbon content within the first region and the third carbon content within the third region are constant, and the second carbon content within the second region increases from an interface between the first region and the second region to an interface between the second region and the third region.

14. A semiconductor device comprising:
a substrate including an active region defined by an element isolation layer;
a word line crossing the active region;
a bit line crossing the active region in a direction different from the word line;
a direct contact connecting between the active region and the bit line;
a buried contact connected to the active region; and
a bit line spacer that extends along a sidewall of the bit line and includes at least one of SiOCN, SiOC, and SiOCF,
wherein the bit line spacer includes a first region, a second region, and a third region sequentially disposed from a first surface adjacent to the bit line to a second surface adjacent to the buried contact, the first region has a first carbon content, the second region has a second carbon content that is greater than the first carbon content, and the third region has a third carbon content that is greater than the second carbon content.

15. The semiconductor device as claimed in claim 14, wherein the first region has a first width, the second region has a second width, the third region has a third width, and a sum of the second width and the third width is smaller than the first width.

16. The semiconductor device as claimed in claim 14, wherein the first carbon content is about 5 at % or less, the second carbon content is about 5 at % or more and about 10 at % or less, and the third carbon content is about 10 at % or more to about 20 at % or less.

17. The semiconductor device as claimed in claim 14, wherein the first carbon content within the first region and the third carbon content within the third region are constant, and the second carbon content within the second region increases from an interface between the first region and the second region to an interface between the second region and the third region.

18. A method for manufacturing a semiconductor device, the method comprising:
forming an element isolation layer within a substrate to define an active region;
forming a word line and a bit line crossing the active region in different directions;
forming a bit line spacer including a first region, a second region, and a third region having different carbon contents to cover the bit line;
patterning the bit line spacer to remove at least a portion of the second region and the third region of the bit line spacer; and
forming a buried contact outside the bit line spacer,
wherein the forming of the bit line spacer includes:
forming the first region having a first carbon content outside the bit line;
forming the second region having a second carbon content that is higher than the first carbon content outside the first region; and
forming the third region having a third carbon content that is higher than the second carbon content outside the second region.

19. The method as claimed in claim 18, wherein the first carbon content is about 5 at % or less, the second carbon content is about 5 at % or more and about 10 at % or less, and the third carbon content is about 10 at % or more to about 20 at % or less.

20. The method as claimed in claim 18, wherein in each of the forming of the first region, the forming of the second region, and the forming of the third region, a unit cycle including supplying an Si source, supplying a C source, supplying an O source, and supplying an N source is repeated, and carbon contents of the first region, the second region, and the third region are differently formed by adjusting a supply time of the C source, a supply quantity of flow of the C source per unit time, a supply time of the O source, and a supply quantity of flow of the O source per unit time.
